(19) United States
(12) Patent Application Publication
(10) Pub. No.: US 2021/0317251 A1
(43) Pub. Date: Oct. 14, 2021

(54) CURABLE COMPOSITION AND ELECTRONIC DEVICE

(71) Applicant: DENSO CORPORATION, Kariya-city (JP)

(72) Inventor: Hiroyuki OKUHIRA, Kariya-city (JP)

(21) Appl. No.: 17/354,715

(22) Filed: Jun. 22, 2021

Related U.S. Application Data
(63) Continuation of application No. PCT/JP2019/044990, filed on Nov. 18, 2019.

(30) Foreign Application Priority Data
Dec. 27, 2018 (JP) 2018-244012

(51) Int. Cl. C08G 18/10; C08G 18/58; C08G 18/80; H05K 5/06

(52) U.S. Cl. CPC C08G 18/10; H05K 5/065; C08G 18/80; C08G 18/58

(57) ABSTRACT

A curable composition comprises a blocked isocyanate compound (PhI) having a plurality of isocyanate groups each protected by phenols (Ph), and an epoxy compound (E) having a plurality of epoxy groups. The curable composition does not contain an isocyanate scavenger which may react with the isocyanate groups nor an epoxy scavenger which may react with the epoxy groups.

### CROSS-REFERENCE TO RELATED APPLICATION

The present application is a continuation application of International Application No. PCT/JP2019/044990 filed on Nov. 18, 2019, which is based on and claims the benefit of priority from Japanese Application No. 2018-244012 filed on Dec. 27, 2018. The contents of these applications are incorporated herein by reference in their entirety.

### BACKGROUND

The present disclosure relates to a curable composition and an electronic device.

Urethane resin is used for various purposes such as a casting material to be filled in a case in which electronics are disposed to protect the electronics, and an adhesive material for bonding a case in which electronics are disposed to a lid component. One known method for forming this type of urethane resin includes heating a curable composition containing a blocked isocyanate compound protected by a blocking agent.

### SUMMARY

An aspect of the present disclosure resides in a curable composition that comprises: a blocked isocyanate compound having a plurality of isocyanate groups each protected by phenols; and

an epoxy compound, wherein

the curable composition does not comprise an isocyanate scavenger nor an epoxy scavenger.

Another aspect of the present disclosure resides in an electronic device comprising: an electronic component;

a case; and

a casting material filled in the case, wherein

the casting material includes a cured product of the curable composition according to the above-described aspect.

Another aspect of the present disclosure resides in an electronic device comprising: an electronic component;

a case;

a lid; and

an adhesive interposed between the case and the lid, wherein

the adhesive includes a cured product of the curable composition according to the above-described aspect.

### BRIEF DESCRIPTION OF THE DRAWINGS

The above and other objects, features, and advantages of the present disclosure will become clearer from the following detailed description with reference to the accompanying drawings. In the drawings,

FIG. 1A shows a schematic diagram of the reaction of liberation of phenols from a blocked isocyanate compound.

FIG. 1B shows a schematic diagram of the reaction in which the phenols and the epoxy compound are bonded.

FIG. 1C shows a schematic diagram of the reaction in which the isocyanate compound and the alcoholic hydroxyl groups are bonded, according to the first embodiment.

FIG. 2 is a cross-sectional view showing key parts of an electronic device in which an electronic component is covered with a sealing member according to the second embodiment.

FIG. 3 is a cross-sectional view showing key parts of an electronic device in which an adhesive is interposed between the case and the lid according to the third embodiment.

### DETAILED DESCRIPTION OF THE PREFERRED EMBODIMENTS

One known method for forming urethane resin includes heating a curable composition containing a blocked isocyanate compound protected by a blocking agent. For example, JP 2002-348530 A discloses a thermosetting coating composition containing polyol or polyamine and a scavenger for thermosetting coating materials as essential components. The scavenger for thermosetting coating materials includes a blocked isocyanate obtained by reacting an isocyanate compound having two or more isocyanate groups in one molecule with a phenol compound. When this coating composition is heated, the phenol compound as the blocking agent is liberated from the blocked isocyanate and the isocyanate compound is produced. The generated isocyanate compound reacts with the polyol or polyamine, which causes the coating composition to cure.

With regard to the coating composition of JP 2002-348530 A, there is a risk that the blocking agent liberated from the blocked isocyanate may volatilize from the coating composition and contaminate the surrounding environment. Further, the blocking agent liberated from the blocked isocyanate may remain in the cured product of the coating composition. In this case, problems such as alteration of the cured product of the coating composition due to the blocking agent, and contamination caused by the blocking agent bleeding out to the surface of the cured product may occur.

An objective of the present disclosure is to provide a curable composition capable of suppressing volatilization and bleed-out of the blocking agent as well as alteration of the cured product due to the blocking agent, and also to provide an electronic component using the curable composition.

An aspect of the present disclosure resides in a curable composition that comprises: a blocked isocyanate compound having a plurality of isocyanate groups each protected by phenols; and

an epoxy compound having a plurality of epoxy groups, wherein

the curable composition does not comprise an isocyanate scavenger that can react with the isocyanate groups nor an epoxy scavenger that can react with the epoxy groups.

Another aspect of the present disclosure resides in an electronic device comprising: an electronic component;

a case for housing the electronic component; and

a casting material filled in the case, wherein

the casting material includes a cured product of the curable composition according to the above-described aspect.

Another aspect of the present disclosure resides in an electronic device comprising: an electronic component;

a case having an opening and housing the electronic component;

a lid covering the opening; and

an adhesive interposed between the case and the lid to bond the case and lid together, wherein

the adhesive includes a cured product of the curable composition according to the above-described aspect.

The curable composition contains a blocked isocyanate compound including phenols as a blocking agent, and an epoxy compound, but it does not contain an isocyanate scavenger which may react with the isocyanate groups nor an epoxy scavenger which may react with the epoxy groups. The curing reaction of the curable composition proceeds as follows.

When the curable composition is heated, the phenols are liberated from the blocked isocyanate compound, and as a result the phenols and an isocyanate compound having isocyanate groups are produced. The phenols liberated from the blocked isocyanate compound react with the epoxy groups of the epoxy compound. Ring-opening of the epoxy group results in generating alcoholic hydroxyl groups in the product of the reaction between the epoxy compound and the phenols. Curing of the curable composition proceeds by the reaction between the alcoholic hydroxyl groups and the isocyanate compound.

As described above, according to the curable composition, the phenols liberated from the blocked isocyanate compound can be incorporated into the molecular structure of the cured product. The phenols incorporated into the molecular structure form chemical bonds with structural units derived from the epoxy compound. As such, volatilization of the phenols during the curing reaction and bleed-out of the phenols from the cured product after curing can be suppressed. Further, since the phenolic hydroxyl groups of the phenol are consumed during the reaction with the epoxy groups, alteration of the cured product due to the phenolic hydroxyl groups can be suppressed.

Thus, according to the above-described aspects. a curable composition capable of suppressing volatilization and bleed-out of the blocking agent as well as alteration of the cured product due to the blocking agent, and also an electronic component including the curable composition can be provided.

### First Embodiment

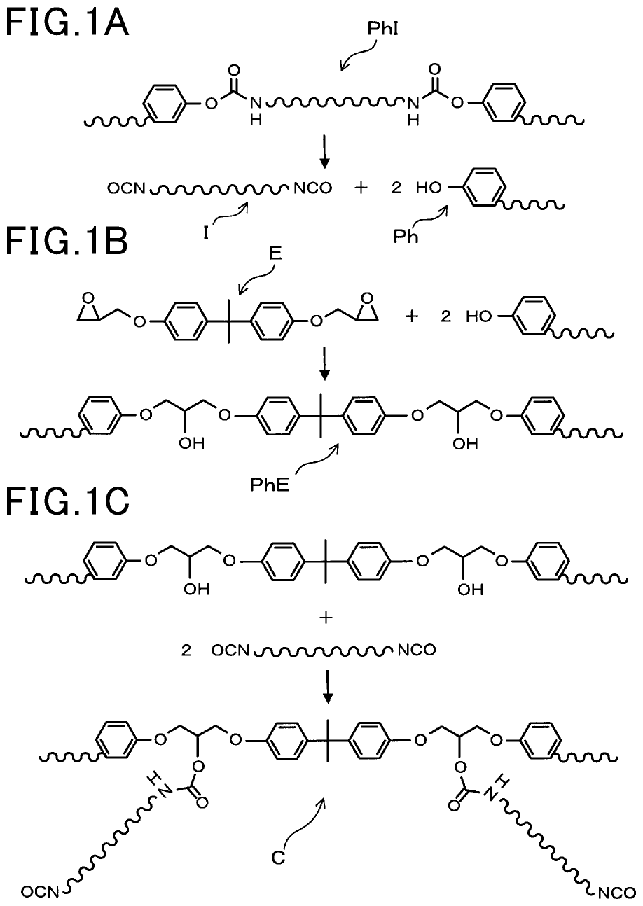

An embodiment relating to the curable composition will be described. The curable composition includes a blocked isocyanate compound PhI having a plurality of isocyanate groups protected by phenols Ph shown in FIG. 1A, and an epoxy compound E having a plurality of epoxy groups shown in FIG. 1B. The curable composition does not contain an isocyanate scavenger which may react with the isocyanate groups nor an epoxy scavenger which may react with the epoxy groups.

Now, the curable composition of the present embodiment will be described in detail.

### Blocked Isocyanate Compound

As shown in FIG. 1, the blocked isocyanate compound PhI has a skeleton structure derived from an isocyanate compound having a plurality of isocyanate groups, and phenols as protective groups bonded to the isocyanate groups. The blocked isocyanate compound may be, for example, a compound obtained by reacting an isocyanate compound I with phenols Ph.

Examples of the isocyanate compound include aromatic diisocyanates such as toluene diisocyanate (TDI) and diphenylmethane diisocyanate (MDI), aliphatic diisocyanates such as hexamethylene diisocyanate (HDI) and isophorone diisocyanate (IPDI), biuret polyisocyanates, polymers of diisocyanate such as isocyanurate polyisocyanates, adduct polyisocyanates, and urethane prepolymers that include a structural unit derived from polyisocyanate and a structural unit derived from polyol. These isocyanate compounds may be used alone or in combination of two or more.

The blocked isocyanate compound preferably has a skeletal structure derived from a urethane prepolymer. That is, the blocked isocyanate compound is preferably a compound formed by reacting a urethane prepolymer with phenols. In such case, the physical characteristics of the cured product of the curable composition can be more easily adjusted in accordance with the molecular weight of the urethane prepolymer and the structural units contained in the urethane prepolymer.

The weight average molecular weight of the urethane prepolymer as the isocyanate compound can be appropriately set within the range of, for example, 200 to 10000. If the weight average molecular weight of the urethane prepolymer is too small, the concentration of urethane bonds rises, which may lead to an increase in the viscosity of the curable composition. As a result, the workability in the coating procedure or casting procedure of the curable composition may deteriorate. On the other hand, if the weight average molecular weight of the urethane prepolymer is too large, the urethane prepolymers may entangle with each other, which may lead to an increase in the viscosity of the curable composition. As a result, the workability in the coating procedure or casting procedure of the curable composition may deteriorate.

These problems can be more easily avoided by setting the weight average molecular weight of the urethane prepolymer within the above-specified range. In order to obtain such effects more reliably, the weight average molecular weight of the urethane prepolymer is more preferably 500 to 8000, and even more preferably 800 to 5000.

The structural unit derived from polyol in the urethane prepolymer is not particularly limited. The urethane prepolymer may have a structural unit derived from, for example, polyether polyol, polyester polyol, (meth)acrylic polyol, castor-oil polyol, or polyolefin polyol. The urethane prepolymer may have one kind of these structural units, or may have two or more kinds.

The polyether polyol may be, for example, a polymer obtained by addition polymerization of alkylene oxide to polyhydric alcohol such as ethylene glycol, glycerin, or pentaerythritol.

The polyester polyol may be, for example, a polymer obtained by condensing a polyhydric alcohol with a polyvalent carboxylic acid such as adipic acid or phthalic acid.

The (meth)acrylic polyol may be, for example, a polymer obtained by addition polymerization of acrylic acid and/or methacrylic acid with olefin, or a hydrogenated product of such polymer.

The castor-oil polyol may be, for example, castor oil or a castor-oil derivative. Castor oil is mainly composed of an ester of a fatty acid containing ricinoleic acid as the main component and glycerin, and it has hydroxyl groups and double bonds originating from the ricinoleic acid. The castor-oil derivative may be, for example, a partially dehydrated castor oil, a transesterified product of castor oil with a low-molecular-weight polyol, polyether polyol, polyester polyol, or the like, and hydrogenated products of these compounds.

The polyolefin polyol may be, for example, a polyolefin polyol with double bonds, or a hydrogenated polyolefin polyol obtained by adding hydrogen to a polyolefin polyol with double bonds so as to reduce the amount of double bonds in the main chain or completely convert the double bonds into single bonds. Specific examples of the hydrogenated polyolefin polyol include hydrogenated polybutadiene and hydrogenated polyisoprene.

Among these polyols, the urethane prepolymer preferably has a structural unit derived from castor-oil polyol, (meth)acrylic polyol, or polyolefin polyol which show good insulation and moisture resistance.

The phenols as the blocking agent are bonded to the isocyanate groups in the blocked isocyanate compound. The phenols may be, for example, unsubstituted phenols such as phenol and naphthol, or phenols with hydrocarbon groups such as cresol, ethylphenol, and propylphenol. These phenols may be used alone or in combination of two or more.

The phenols preferably have a chain hydrocarbon group bonded to an aromatic ring. This facilitates liberation of the phenol from the isocyanate groups at a relatively low temperature. As a result, volatilization of phenols during the curing reaction and bleed-out of phenols from the cured product after curing can be suppressed more effectively. Further, since the hygroscopicity of the cured product can be reduced in such case, deterioration of the cured product due to the phenolic hydroxyl groups, such as deterioration caused by hydrolysis, can be effectively suppressed.

When the phenols have a chain hydrocarbon group, the structure of the chain hydrocarbon group may either be straight or branched. Further, the chain hydrocarbon group may or may not have an unsaturated bond.

In order to further enhance the above-mentioned effects, it is more preferable to use phenols having a chain hydrocarbon group with 8 or more carbon atoms. Examples of such phenols include octylphenol, nonylphenol, and decylphenol. Further, a mixture of phenols having chain hydrocarbon groups with 8 or more carbon atoms, such as cardanol and hydrogenated cardanol, can also be used.

In order to further enhance the above-mentioned effects, it is more preferable that the chain hydrocarbon group is located at the meta position with respect to the phenolic hydroxyl group.

The content of isocyanate groups in the curable composition is preferably 0.8 to 1.2 times the content of epoxy groups in terms of molar ratio.

In such case, since the amount of phenol liberated from the blocked isocyanate compound would be about the same as the amount of epoxy groups, the phenol liberated from the blocked isocyanate compound can be more easily incorporated into the cured product. As a result, problems such as volatilization of phenols during the curing reaction, bleed-out of phenols from the cured product, and deterioration of the cured product due to phenols can be suppressed more effectively.

Further, since the amount of isocyanate groups generated by the liberation of phenols would be about the same as the amount of epoxy groups in such case, the isocyanate compound and the reaction product of the epoxy compound and the phenols can be reacted more efficiently. As a result, the amount of unreacted components in the cured product can be further reduced, and thus variation in the physical properties of the cured products can be further reduced.

### Epoxy Compound

The epoxy compound (E) has a plurality of epoxy groups in one molecule as shown in FIG. 1B. Examples of the epoxy compound include glycidyl ether epoxy resin, glycidyl amine epoxy resin, glycidyl ester epoxy resin, high-molecular-weight epoxy resin in which an epoxy group is bonded to a terminal of a polymer such as polyether, polyester, polybutadiene, or polyurethane, and epoxy resin with a polyaromatic ring such as naphthalene or biphenyl. These epoxy compounds may be used alone or in combination of two or more.

The epoxy compound is preferably a glycidyl ether epoxy resin or a glycidyl amine epoxy resin that has an epoxy equivalent of 150 to 2000 and has a bisphenol skeleton such as bisphenol or bisphenol F. These epoxy resins can be easily mixed when blended with another resin or the like. Further, a curable composition containing these epoxy resins tends to be liquid at room temperature. Furthermore, a stronger cured product can be obtained by curing a curable composition containing these epoxy resins.

Note that the epoxy equivalent described above is a value obtained by the method specified in JIS K7236: 2009.

### Other Components

In addition to the blocked isocyanate compound and the epoxy compound as essential components, the curable composition may include one or more additives such as a filler, a flame retardant, an auxiliary agent for flame retardant, a mold release agent, and a catalyst as long as they do not impair the above-mentioned effects.

However, if the curable composition contains an isocyanate scavenger which may react with the isocyanate groups or an epoxy scavenger which may react with the epoxy groups, the above-mentioned effects may be impaired. Examples of isocyanate scavengers include alcohols, amines, and carboxylic acids. Examples of epoxy scavengers include primary amines, secondary amines, tertiary amines, acid anhydrides, and phenols.

That is, as described above, the curing reaction of the curable composition includes a first-stage reaction in which the blocked isocyanate compound PhI separates into an isocyanate compound I and phenols Ph (see FIG. 1A), a second-stage reaction in which the phenols Ph reacts with the epoxy compound E (see FIG. 1B), and a third-stage reaction in which the product PhE of the second-stage reaction reacts with the isocyanate compound Ito form a cured product C (see FIG. 1C). As an example, FIG. 1 shows an example reaction between a blocked isocyanate compound PhI having two isocyanate groups in one molecule and bisphenol A diglycidyl ether as the epoxy compound E.

When an isocyanate scavenger is present in the curable composition, the isocyanate groups of the isocyanate compound I generated by the first-stage reaction may react with the isocyanate scavenger. And if the isocyanate groups are consumed by the reaction with the isocyanate scavenger, the progress of the third-stage reaction may be hindered. As a result, it becomes difficult to sufficiently cure the curable composition, and the amount of unreacted components in the cured product may increase. Further, in such case, since the isocyanate compound I reacts with the isocyanate scavenger after the liberation of the phenols Ph from the blocked isocyanate compound PhI, the storage stability may deteriorate.

In addition, when an epoxy scavenger is present in the curable composition, the epoxy groups of the epoxy compound E may react with the epoxy scavenger. And if the epoxy groups are consumed by the reaction with the epoxy scavenger, the progress of the second-stage reaction may be hindered. As a result, it becomes difficult to sufficiently cure the curable composition, and the amount of unreacted components in the cured product may increase. Further, in such case, the risk of volatilization and bleed-out of the phenols Ph liberated from the blocked isocyanate compound Ph, as well as alteration of the cured product due to the phenols Ph may increase.

Therefore, it is preferable that the content of the isocyanate scavenger and the content of the epoxy scavenger in the curable composition are as small as possible, and it is particularly preferable that the curable composition does not contain an isocyanate scavenger or an epoxy scavenger. The concept of “does not contain an isocyanate scavenger or an epoxy scavenger” includes the case where the content of the isocyanate scavenger and the content of the epoxy scavenger are zero, as well as the case where the isocyanate scavenger and/or the epoxy scavenger are contained in such an amount that does not impair the above-mentioned effects.

More specifically, when the number of moles of active hydrogen of the isocyanate scavenger is 1/10 or less of the number of moles of isocyanate groups in the blocked isocyanate compound, the isocyanate scavenger has almost no impact on the curing reaction, and thus it can be considered that an isocyanate scavenger is not contained. Similarly, when the number of active points in the epoxy scavenger, that is, the number of parts that can react with the epoxy groups is 1/10 or less of the number of moles of epoxy groups in the epoxy compound, the epoxy scavenger has almost no impact on the curing reaction, and thus it can be considered that an epoxy scavenger is not contained.

According to the curable composition containing a blocked isocyanate compound and an epoxy compound but not containing an isocyanate scavenger or an epoxy scavenger, the above-mentioned problems can be avoided, and volatilization and bleed-out of the blocking agent as well as alteration of the cured product due to the blocking agent can be suppressed.

### Second Embodiment

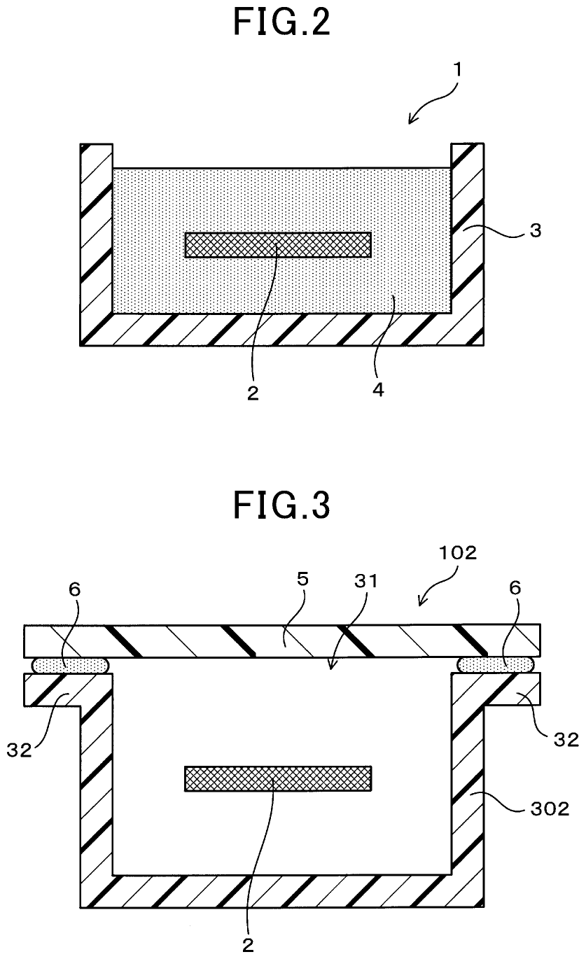

In this embodiment, an embodiment of an electronic device in which the curable composition according to the first embodiment is used as a casting material will be described. As shown in FIG. 2, the electronic device 1 according to the present embodiment has an electronic component 2, a case 3 for housing the electronic component 2, and a casting material 4 filled in the case 3. The casting material 4 is composed of a cured product of the curable composition.

The case 3 of the electronic device 1 of the present embodiment has a box-like shape with a bottom, and one of its faces is open. The electronic component 2 is housed in the case 3. Further, the case 3 is filled with the casting material 4, and the entire surface of the electronic component 2 is covered with the casting material 4. Although not shown in the figure, the electronic component 2 may have wiring, terminals, or the like that protrude(s) from the casting material 4 to electrically connect the component with a peripheral device of the electronic device 1.

The electronic component 2 may be, for example, an electronic control device such as an engine control unit.

For example, the electronic device 1 of the present embodiment can be manufactured as follows. First, after placing the electronic component 2 in the case 3, the curable composition is injected into the case 3. The injection of the curable composition is stopped after the entire surface of the electronic component 2 is covered with the curable composition.

Then, the casting material 4 can be formed by heating the electronic device 1 to cure the curable composition. As the curable composition does not need to take in, for example, moisture or oxygen from outside the curable composition for the curing reaction to proceed, the deeper part of the composition cures well. Therefore, using the curable composition, the electronic component 2 in the case 3 can be protected by a fully cured casting material 4.

### Third Embodiment

In this embodiment, an embodiment of an electronic device 102 in which the curable composition according to the first embodiment is used as an adhesive will be described. Note that, among the reference signs used in the third and following embodiments, the same reference signs as those used in the earlier embodiment(s) denote components or the like that are similar to those of the earlier embodiment(s) unless otherwise noted.

The electronic device 102 of the present embodiment includes the electronic component 2, a case 302 having an opening 31 and housing the electronic component 2, a lid 5 covering the opening 31, and an adhesive 6 applied between the case 302 and the lid 5 to bond them together. The adhesive 6 is composed of a cured product of the curable composition.

As shown in FIG. 3, the electronic component 2 of the present embodiment is housed in a box-shaped case 302 with an open side. As with the second embodiment, the electronic component 2 may be an electronic control device such as an engine control unit.

The case 302 has a flange part 32 extending outward from the rim of the opening 31. The lid 5 is placed so as to cover the flange part 32 and the opening 31 of the case 302. Between the flange part 32 and the lid 5, the adhesive 6 is applied over the entire circumference of the flange part 32.

For example, the electronic device 102 of the present embodiment can be manufactured as follows. First, after placing the electronic component 2 in the case 302, the curable composition is applied over the entire circumference of the flange part 32. Then, after placing the lid 5 on the case 302, the electronic device 102 is heated to cure the curable composition. The adhesive 6 can thus be formed between the lid 5 and the flange part 32 so as to bond the case 302 to the lid 5.

### EXPERIMENTAL EXAMPLES

Specific examples of the composition of the curable composition will be described. In this example, first, the polyol and isocyanate shown in Table 1 were reacted in the presence of a tin catalyst to prepare a urethane prepolymer as the isocyanate compound. “Isocyanate group content” in Table 1 shows the content of isocyanate groups in each urethane prepolymer. Specifically, the compounds used in the preparation of the urethane prepolymer are as follows.

Acrylic polyol: “ARUFON (registered trademark) UH-2000” manufactured by Toagosei Co., Ltd.
Hydrogenated polybutadiol: “GI-1000” manufactured by Nippon Soda Co., Ltd.
Modified MDI: “Millionate MTL” manufactured by Tosoh Corporation
Tin catalyst: Dibutyltin dilaurate

TABLE 1

| | | Urethane prepolymer Urethane prepolymer | |
|---|---|---|---|
| | | 1 | 2 |
| Acrylic polyol | Parts by | 80 | — |
| mass | | | |
| Hydrogenated | Parts by | 20 | — |
| polybutadiol | mass | | |
| Castor oil polyol | Parts by | — | 100 |
| | mass | | |
| Isocyanate | Parts by | 30.4 | 23.2 |
| | mass | | |
| Tin catalyst | Parts by | 0.002 | 0.002 |
| | mass | | |
| Isocyanate group | Mass% | 3 | 2.7 |
| content | | | |

Next, a blocked isocyanate compound was prepared by reacting 100 parts by mass of the urethane prepolymer with the blocking agent in the amount shown in Table 2. An epoxy compound and other compounds were added to the blocked isocyanate compound at the corresponding ratios shown in Tables 2 and 3 to prepare a curable composition. In the row of “NCO/Epoxy” in Tables 2 and 3, the molar ratios of the amount of isocyanate groups to the amount of epoxy groups in the curable composition are shown. The other compounds are specifically as follows.

Bisphenol A epoxy resin: “jER (registered trademark) 828” manufactured by Mitsubishi Chemical Corporation, epoxy equivalent: 188
Bisphenol F epoxy resin: “jER807” manufactured by Mitsubishi Chemical Corporation, epoxy equivalent: 168
Plasticizer: “TOTM”, tris(2-ethylhexyl) trimellitate manufactured by J-PLUS Co., Ltd.
Catalyst: “JC-263”, triphenylphosphine manufactured by Johoku Chemical Co., Ltd.

Using the curable compositions (test agents 1 to 13) obtained as described above, storage stability, curability, and volatility of the blocking agent were evaluated.

### Storage Stability

The viscosity of each test agent was measured after placing them in an environment of 60° C. for 2 days, and the ratio of the viscosity after 2 days to the viscosity immediately after the preparation was calculated. The ratio of viscosity after 2 days to the viscosity immediately after preparation of each test agent was as shown in the row labelled “storage stability” in Tables 2 and 3. In the evaluation of storage stability, the test agent was judged acceptable when the viscosity after 2 days was equal to or lower than 1.5 times the viscosity immediately after preparation as it indicates good storage stability, and judged unacceptable when the viscosity after 2 days was higher than 1.5 times the viscosity immediately after preparation as it indicates poor storage stability.

### Curability

Each test agent was heated at 150° C. for an hour and then naturally cooled to room temperature. The surface of the obtained cured product was touched by hand to evaluate if there is any tack. In the row of “curability” in Tables 2 and 3, the symbol “A” was given when the surface of the cured product was not tacky (that is, there was no tack), the symbol “B” was given when the surface of the cured product was tacky, and the symbol “C” was given when the test agent was not sufficiently cured and the uncured test agent adhered to the hand. In the evaluation of curability, samples that were assigned symbols “A” and “B” were judged acceptable as they indicate good curability, and samples that were assigned symbol “C” were judged unacceptable as it indicates poor curability.

### Volatility of Blocking Agent

Each test agent was heated at 150° C. for an hour and then naturally cooled to room temperature. The smell of the obtained cured product was checked to evaluate if there is any odor. In the row of “volatility of blocking agent” in Tables 2 and 3, the symbol “A” was given when the cured product did not have an odor, and the symbol “B” was given when the cured product had an odor. In the evaluation of volatility of the blocking agent, cured products that were assigned symbol “A” and did not have an odor were judged acceptable as it indicates that the amount of volatilization of the blocking agent is small, and cured products that were assigned symbol “B” and had an odor were judged unacceptable as it indicates that the blocking agent has volatilized.

TABLE 2

| | | | | Test | Test | Test | Test | Test | Test | Test |
|---|---|---|---|---|---|---|---|---|---|---|
| | | | | agent 1 | agent 2 | agent 3 | agent 4 | agent 5 | agent 6 | agent 7 |
| Blocked | Isocyanate | Urethane | Parts by mass | 100 | 100 | 100 | 100 | — | 100 | 100 |
| isocyanate | compound | prepolymer 1 | | | | | | | | |
| compound | | Urethane | Parts by mass | — | — | — | — | 100 | — | — |
| | | prepolymer 2 | | | | | | | | |
| | Blocking | Cardanol | Parts by mass | 21.4 | 21.4 | 21.4 | 21.4 | 19.3 | — | — |
| | agent | Hydrogenated | Parts by mass | — | — | — | — | — | 21.6 | — |
| | | cardanol | | | | | | | | |
| | | Nonylphenol | Parts by mass | — | — | — | — | — | — | 8.1 |
| | | ε-Caprolactam | Parts by mass | — | — | — | — | — | — | — |
| | | Methylethyl | Parts by mass | — | — | — | — | — | — | — |
| | | ketone oxime | | | | | | | | |
| Epoxy | Bisphenol A epoxy resin | | Parts by mass | 8.6 | — | 7.7 | 9.5 | 12.5 | 8.6 | 8.6 |
| compound | Bisphenol F epoxy resin | | Parts by mass | — | 7.7 | — | — | — | — | — |
| Other | Isocyanate | Octanediol | Parts by mass | — | — | — | — | — | — | — |
| components | scavenger | | | | | | | | | |
| | Plasticizer | Tris(2-ethylhexyl) | Parts by mass | 10 | 10 | 10 | 10 | 10 | 10 | 10 |
| | | trimellitate | | | | | | | | |
| | Catalyst | Triphenylphosphine | Parts by mass | 1 | 1 | 1 | 1 | 1 | 1 | 1 |

| | | | | | | | | | |
|---|---|---|---|---|---|---|---|---|---|
| Molar ratio | NCO/epoxy group | — | 1.0 | 1.0 | 0.9 | 1.1 | 1.0 | 1.0 | 1.0 |
| Storage stability | Viscosity mtio | Times | 1.0 | 1.0 | 1.0 | 1.0 | 1.0 | 1.0 | 1.0 |

| | | | | | | | | |
|---|---|---|---|---|---|---|---|---|
| Curability | — | A | A | A | A | A | A | A |
| Volatility of blocking agent | — | A | A | A | A | A | A | A |

TABLE 3

| | | | | Test | Test | Test | Test | Test | Test |
|---|---|---|---|---|---|---|---|---|---|
| | | | | agent 8 | agent 9 | agent 10 | agent 11 | agent 12 | agent 13 |
| Blocked | Isocyanate | Urethane | Parts by mass | 100 | 100 | 100 | 100 | 100 | 100 |
| isocyanate | compound | prepolymer 1 | | | | | | | |
| compound | | Urethane | Parts by mass | — | — | — | — | — | — |
| | | prepolymer 2 | | | | | | | |
| | Blocking | Cardanol | Parts by mass | 21.4 | 21.4 | — | — | — | — |
| | agent | Hydrogenated | Parts by mass | — | — | — | — | — | — |
| | | cardanol | | | | | | | |
| | | Nonylphenol | Parts by mass | — | — | — | — | — | — |
| | | ε-Caprolactam | Parts by mass | — | — | — | 8.1 | — | — |
| | | Methylethyl | Parts by mass | — | — | 6.2 | — | 4.0 | 6.2 |
| | | ketone oxime | | | | | | | |
| Epoxy | Bisphenol A epoxy resin | | Parts by mass | 6.0 | 11.2 | 8.6 | 8.6 | — | 8.6 |
| compound | Bisphenol F epoxy resin | | Parts by mass | — | 7.7 | — | — | — | — |
| Other | Isocyanate | Octanediol | Parts by mass | — | — | — | — | 3.5 | 3.5 |
| components | scavenger | | | | | | | | |
| | Plasticizer | Tris(2-ethylhexyl) | Parts by mass | 10 | 10 | 10 | 10 | 10 | 10 |
| | | trimellitate | | | | | | | |
| | Catalyst | Triphenylphosphine | Parts by mass | 1 | 1 | 1 | 1 | 1 | 1 |

| | | | | | | | | |
|---|---|---|---|---|---|---|---|---|
| Molar ratio | NCO/epoxy group | — | 0.7 | 1.3 | 1.0 | 1.0 | 1.0 | 1.0 |
| Storage stability | Viscosity mtio | Times | 1.0 | 1.0 | 1.3 | 1.0 | 2.8 | 1.0 |

| | | | | | | | |
|---|---|---|---|---|---|---|---|
| Curability | — | B | B | C | C | A | B |
| Volatility of blocking agent | — | A | A | B | A | B | B |

As shown in Tables 2 and 3, each of the test agents 1 to 9 contains a blocked isocyanate compound and an epoxy resin as an epoxy compound, but does not contain an isocyanate scavenger or an epoxy scavenger. Therefore, these test agents can suppress volatilization of phenols from the cured product. In addition, these test agents have good storage stability and curability. From these results, it can be understood that, with regard to the test agents 1 to 9, the phenols that had been liberated from the blocked isocyanate compound could be taken into the cured product.

As shown in Table 3, since the test agent 10 was prepared using methylethyl ketone oxime, which is not a phenol, as the blocking agent, a decrease in storage stability, deterioration in curability, and an increase in the volatilization amount of the blocking agent were seen.

Since the test agent 11 was prepared using ϵ-caprolactam, which is not a phenol, as the blocking agent, deterioration in curability was seen.

The test agent 12 does not contain an epoxy compound but contains octanediol which can react with isocyanate groups. Therefore, the blocking agent liberated from the blocked isocyanate compound was not incorporated into the cured product and volatilized more easily from the cured product.

The test agent 13 contains an epoxy compound but also contains octanediol. Therefore, the blocking agent liberated from the blocked isocyanate compound was not incorporated into the cured product and volatilized more easily from the cured product. In addition, the unreacted epoxy compound caused the curability to slightly decrease.

The present disclosure is not limited to the above embodiments, and can be applied to various embodiments without departing from the gist of the present disclosure.

What is claimed is:

1. A curable composition comprising: a blocked isocyanate compound having a plurality of isocyanate groups each protected by phenols; and
an epoxy compound having a plurality of epoxy groups, wherein
the curable composition does not comprise an isocyanate scavenger that can react with the isocyanate groups nor an epoxy scavenger that can react with the epoxy groups, and
the phenols have a chain hydrocarbon group bonded to an aromatic ring and having 8 or more carbon atoms.

2. The curable composition according to claim 1, wherein the blocked isocyanate compound has a skeletal structure derived from a urethane prepolymer.

3. The curable composition according to claim 1, wherein a content of the isocyanate groups is 0.8 to 1.2 times a content of the epoxy groups in terms of molar ratio.

4. The curable composition according to claim 1, wherein the chain hydrocarbon group is located at the meta position with respect to the phenolic hydroxyl group.

5. An electronic device comprising: an electronic component;
a case for housing the electronic component; and
a casting material filled in the case, wherein
the casting material includes a cured product of the curable composition according to claim 1.

6. An electronic device comprising: an electronic component;
a case having an opening and housing the electronic component;
a lid covering the opening; and
an adhesive interposed between the case and the lid to bond the case and the lid together, wherein
the adhesive includes a cured product of the curable composition according to claim 1.
